(19) United States
(12) Patent Application Publication
(10) Pub. No.: US 2016/0004137 A1
(43) Pub. Date: Jan. 7, 2016

(54) DISPLAY ASSEMBLY INCLUDING TWO SUPERPOSED DISPLAY DEVICES

(71) Applicant: The Swatch Group Research and Development Ltd, Marin (CH)

(72) Inventor: Michel SAGARDOYBURU, Neuchatel (CH)

(73) Assignee: The Swatch Group Research and Development Ltd, Marin (CH)

(21) Appl. No.: 14/735,630

(22) Filed: Jun. 10, 2015

(30) Foreign Application Priority Data
Jul. 4, 2014 (EP) 14175864.9
Aug. 20, 2014 (EP) 14181607.4

(51) Int. Cl. G02F 1/31; H01L 51/52; G02F 1/13363; H01L 27/32; G06F 1/16; G02F 1/1335

(52) U.S. Cl. CPC G02F 1/31; G06F 1/163; G02F 1/133528; G02F 1/133536; G02F 1/13363; H01L 27/3267; H01L 51/5218; H01L 51/5221; G02F 2001/133541; G02F 2001/133638

(57) ABSTRACT

Display assembly for a portable object, said display assembly including a first reflective display device located on the side of an observer, a second emissive display device being disposed underneath the first reflective display device.

This application claims priority from European Patent Application No 14175864.9 filed Jul. 4, 2014 and European Patent Application No 14181607.4 filed Aug. 20, 2014, the entire disclosure of which is hereby incorporated herein by reference.

### FIELD OF THE INVENTION

The present invention concerns a display assembly including two superposed display devices. More specifically, the present invention concerns such a display assembly intended to be housed inside a portable object such as a wristwatch.

### BACKGROUND OF THE INVENTION

The readability of the information displayed by active digital display devices, such as liquid crystal display devices or organic light-emitting diode display devices is very dependent on ambient lighting conditions. With some digital display devices, the displayed information can be read in good conditions in a brightly lit environment, but is, however, difficult to read in a dark environment. Conversely, other categories of digital display devices provide a good quality display in twilight or darkness, but are virtually unusable in broad daylight.

By way of example, let us consider transflective liquid crystal display cells, that is to say liquid crystal cells capable of displaying information that will be visible in full sunlight by means of a reflection phenomenon, and which will also be visible at night by transmission by using a backlighting device. Such transflective liquid crystal display cells are optimised to provide the best possible reflection of sunlight and thus to ensure good readability of the displayed information in bright conditions. However, in order for such transflective liquid crystal display cells to be capable of the best possible reflection of sunlight, their transmission efficiency is greatly restricted. Thus, when the backlighting device is activated to allow the displayed information to be read in twilight, most of the light generated by the backlighting device is lost in absorption phenomena. Energy efficiency is therefore poor. Further, the optical qualities of the information displayed by the liquid crystal cell are greatly dependent on the viewing angle.

As regards emissive display devices, such as organic light-emitting diode display devices, these devices have superior optical qualities to those of liquid crystal display cells, since the optical qualities are not dependent on the viewing angle. Nonetheless, these high quality emissive display devices do not permit a reflective mode of operation. The information that they display is thus very readable indoors or in darkness, but becomes difficult to read once viewed outdoors. To overcome this problem, it is necessary to increase the amount of current supplied to emissive display devices to ensure a minimum level of readability. Further, even in normal conditions of use, these emissive display devices use more electric current than a reflective liquid crystal display cell. Their electrical power consumption is such that it is not possible to leave them permanently switched on, for example in a watch, whose only source of energy is a battery which is usually required to last for more than one year.

### SUMMARY OF THE INVENTION

It is an object of the present invention to overcome the aforementioned problems in addition to others by providing a display assembly for a portable object such as a wristwatch which operates properly both in a brightly lit environment and in a dark environment.

To this end, the present invention concerns a display assembly for a portable object, the display assembly including a first reflective display device located on the side of an observer, this first display device being capable of switching between a transparent state when it is at rest and a reflective state when it is activated, a second emissive display device being disposed underneath the first reflective display device.

According to a complementary feature of the invention, the reflective display device is bonded on the emissive display device.

According to another feature of the invention, the reflective display device is bonded on the emissive display device by means of an adhesive film or a liquid adhesive layer.

As a result of these features, the present invention provides a display assembly for a portable object, such as a wristwatch, which operates in an optimum manner regardless of the ambient lighting conditions. In broad daylight, the information will preferably be displayed by the reflective display device. Indeed, this reflective display device, utilising sunlight to display information, is energy efficient. It can therefore remain permanently switched on and offers good readability of information. Conversely, in twilight or darkness, the information will be displayed by the emissive display device. Such an emissive display device uses more current than a reflective display device, but the information displayed thereby is visible at night or in darkness with very good optical properties which are notably independent of the viewing angle.

According to a first variant embodiment of the invention, the first display device includes a reflective liquid crystal display cell, and the second display device includes an emissive organic light-emitting diode display cell.

According to a second variant embodiment of the invention, the first display device includes a reflective liquid crystal display cell, and the second display device includes a transmissive liquid crystal display cell underneath which is arranged a backlight device.

As a result of these other features, the present invention provides a display assembly that makes it possible to permanently display information in a simple, readable manner, with low electrical energy consumption. In particular, the present invention provides a display assembly making it possible to display a large amount of information which is visible even in the dark.

### BRIEF DESCRIPTION OF THE DRAWINGS

Other features and advantages of the present invention will appear more clearly from the following detailed description of several example embodiments of the display assembly according to the invention, these examples being given solely by way of non-limiting illustration with reference to the annexed drawing, in which:

FIG. 1 is a cross-sectional view of a first embodiment of a display assembly according to the invention which includes a reflective liquid crystal display cell bonded on an organic light-emitting diode display cell.

FIGS. 2A to 2D illustrate schematically the operating mode of the display assembly illustrated in FIG. 1 depending on whether the liquid crystal display cell and the organic light-emitting diode display cell are active or passive.

FIG. 3 is a cross-sectional view of a variant embodiment of the display assembly according to the invention illustrated in FIG. 1 wherein a single polarizer liquid crystal display cell is bonded on an organic light-emitting diode display cell.

FIGS. 4A to 4D illustrate schematically the operating mode of the display assembly illustrated in FIG. 3 depending on whether the single polarizer liquid crystal display cell and the organic light-emitting diode display cell are active or passive.

FIG. 5 is a cross-sectional view of a second embodiment of a display assembly according to the invention which includes a reflective liquid crystal display cell bonded on a backlit transmissive liquid crystal display cell.

### DETAILED DESCRIPTION OF ONE EMBODIMENT OF THE INVENTION

The present invention proceeds from the general inventive idea which consists in providing a display assembly which is capable of displaying information in a readable manner both in broad daylight and in twilight or darkness and which has optimal electrical energy consumption. To achieve this object, the present invention teaches combining a display device that is arranged to be capable of switching between a rest state in which it is transparent, and an active state, in which it is capable of reflecting ambient light, with an emissive display device. The reflective display device is typically a liquid crystal display cell, whereas the emissive display device is typically an organic light-emitting display cell or a transmissive liquid crystal display cell with which a backlight device is associated. For the display of information in broad daylight, use of the reflective display device is preferred, which, by the reflection of sunlight, can display information in a clear and readable manner with low electrical energy consumption. For the display of information in twilight or darkness, use of the emissive display device is preferred. Owing to its excellent optical properties, particularly in terms of contrast and colour reproduction, such an emissive display device makes it possible to display a large amount of information in a highly readable manner. In particular, the readability of the displayed information is not dependent on the viewing angle. Further, despite the twilight or darkness, it is possible to significantly reduce the energy consumption of such an emissive display device while ensuring good readability of the displayed information. There is therefore provided a display assembly which includes a reflective display device placed on top of the stack and which is capable of permanently displaying information with very low energy consumption, and an emissive display device, placed at the base of the stack and which is capable of displaying information on demand in a highly readable manner in twilight or darkness.

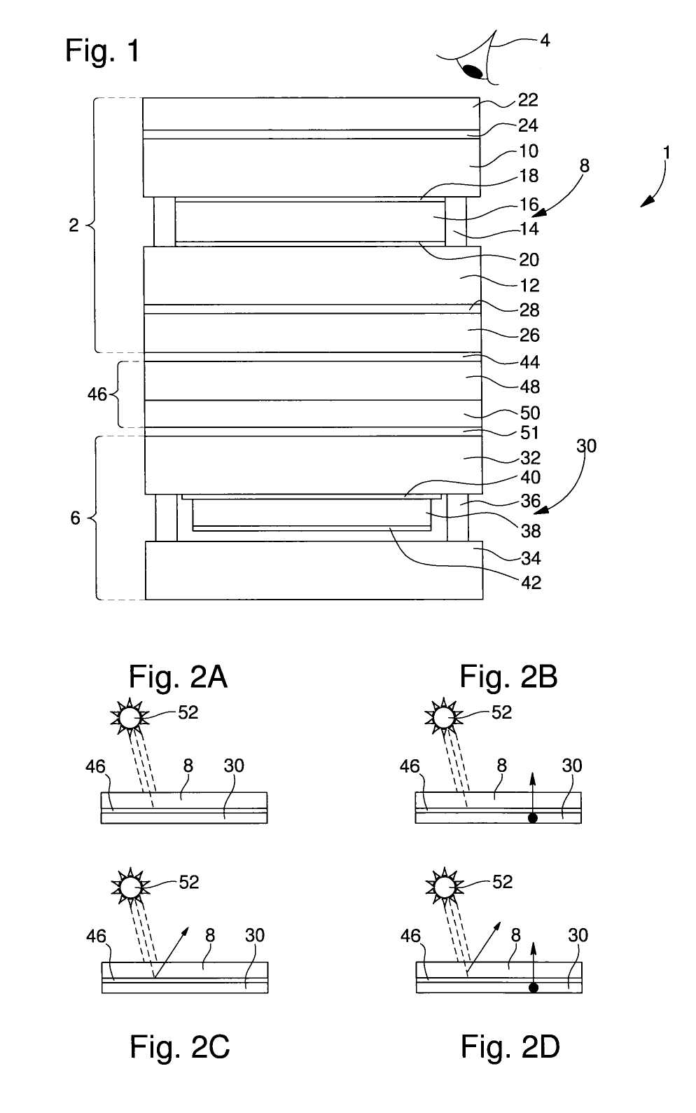

FIG. 1 is a cross-sectional view of a first embodiment of a display assembly according to the invention. Designated as a whole by the general reference numeral 1, this display assembly includes a first reflective display device 2 located on the side of an observer 4, and a second emissive display device 6, arranged underneath the first reflective display device 2.

According to the invention, the first reflective display device 2, which is reflective in a first switching state and which is transparent in a second switching state, includes a liquid crystal display cell 8. This liquid crystal display cell 8 includes, in a non-limiting manner, a front substrate 10 located on the side of the observer 4 and a rear substrate 12 which extends parallel to and remote from front substrate 10. These two front and rear substrates 10, 12 are made of a transparent material such as glass or plastic. The two front and rear substrates 10 and 12 are joined to each other by a sealing frame 14 which delimits a closed volume for containing a liquid crystal 16 whose optical properties are modified by application of a suitable voltage at a particular crosspoint between transparent electrodes 18 arranged on a lower face of front substrate 10 and transparent counter electrodes 20 arranged on an upper face of rear substrate 12. Electrodes 18 and counter electrodes 20 are made of a transparent, electrically conductive material such as indium-zinc oxide, or indium-tin oxide known as ITO.

In the case of the present invention, any of the liquid crystal phases, such as twisted nematic (TN), super twisted nematic (STN) or vertically aligned (VA), may be envisaged. Likewise, all addressing schemes, such as direct addressing, active matrix addressing, or passive matrix multiplexing addressing may be envisaged.

An absorbent polarizer 22 is bonded on an upper face of front substrate 10 by means of an adhesive layer 24. This adhesive layer 24 may be formed of an adhesive film or of a liquid adhesive layer. The adhesive used to bond absorbent polarizer 22 on liquid crystal display cell 8 may be transparent or slightly diffusing depending on whether specular or diffuse reflection is required. Absorbent polarizer 22 may be, for example, an iodine or dye type polarizer.

A reflective polarizer 26 is bonded on a lower face of rear substrate 12 by means of an adhesive layer 28 which may be transparent or slightly diffusing depending on whether specular or diffuse reflection is required. Reflective polarizer 26 may be of the wire grid polarizer type. It may also be a polarizer composed of a series of birefringent layers which cause polarization reflection or transmission by the effect of constructive or destructive interferences, such as dual brightness enhancement film (DBEF) or APF polarizers, sold by the American company 3M®.

Again, according to the invention, the second emissive display device 6 includes an emissive display cell 30 with organic light-emitting diodes which will be referred to below as “OLEDs”. This OLED display cell 30 includes a transparent substrate 32 made of glass or of a plastic material and an encapsulation cover 34 which extends parallel to and remote from substrate 32. Substrate 32 and encapsulation cover 34 are joined to each other by a sealing frame 36 which delimits a closed volume shielded from air and humidity to contain a stack of light-emitting layers generally designated by the reference number 38. An upper transparent electrode 40, made for example of indium-tin oxide or ITO, and a lower reflective electrode 42, made for example using a material such as aluminium or silver, calcium or a metal alloy of aluminium or silver with calcium, lithium or magnesium, are structured on either side of the stack of light-emitting layers 38.

Liquid crystal display cell 8 is, with respect to observer 4, disposed above OLED cell 30. Preferably, liquid crystal display cell 8 is bonded on OLED cell 30 by means of a transparent adhesive layer 44 formed of an adhesive film or of a liquid adhesive layer. It is preferable to bond liquid crystal display cell 8 on OLED cell 30 to avoid problems of stray reflections between the two cells which would degrade the optical quality of display assembly 1 according to the invention.

A circular polarizer 46, formed of an absorbent polarizer 48 and of a quarter-wave plate 50, is inserted between liquid crystal display cell 8 and OLED cell 30. The purpose of this circular polarizer 46 is to absorb ambient light and thus give a black appearance to OLED cell 30 when the latter is switched off. Quarter-wave plate 50 is secured to substrate 32 by means of an adhesive layer 51.

According to a complementary feature of the invention, the axis of transmission of reflective polarizer 26 of liquid crystal display cell 8 is oriented parallel to the axis of transmission of absorbent polarizer 48 belonging to circular polarizer 46 of OLED display cell 30. In this manner, the linearly polarized light emitted by OLED display cell 30 passes through liquid crystal display cell 8 when liquid crystal display cell 8 is in transmissive mode. Conversely, the ambient light that arrives in the OLED display cell by passing through liquid crystal display cell 8 is circularly polarized by circular polarizer 46. This light is then reflected by reflective lower electrode 42, which causes a reversal in the direction of rotation of circular polarization and absorption of the light by circular polarizer 46. Display assembly 1 according to the invention thus appears black to observer 4.

FIGS. 2A to 2D illustrate schematically the operating mode of display assembly 1 of the invention depending on whether or not liquid crystal display cell 8 or OLED display cell 30 is in use. Hereafter, it will be assumed that liquid crystal display cell 8 is a twisted nematic cell. This example is given solely by way of non-limiting illustration given that it is easier to describe the operation of display assembly 1 according to the invention in the case where liquid crystal display cell 8 is of the twisted nematic type. It will be understood, however, that liquid crystal display cell 8 may be of another type, such as super twisted nematic or vertically aligned.

More specifically, in FIG. 2A, liquid crystal display cell 8 and OLED display cell 30 are both switched off. Liquid crystal display cell 8 is therefore transparent. The ambient light, designated by the reference numeral 52, is linearly polarized by absorbent polarizer 22. Ambient light 52 then undergoes a rotation of 90° when it passes through liquid crystal display cell 8. As the axis of transmission of reflective polarizer 26 extends in a direction perpendicular to the direction in which the axis of transmission of absorbent polarizer 22 extends, reflective polarizer 26 lets ambient light 52 pass through without modification, and ambient light 52 propagates in the direction of OLED display cell 30. Before penetrating OLED display cell 30, ambient light 52 is circularly polarized by circular polarizer 46. Finally, ambient light 52 passes through OLED display cell 30 in which it is reflected onto reflective lower electrode 42. After reflection onto reflective lower electrode 42, the direction of rotation of circular polarization of light is reversed, so that the light is absorbed by circular polarizer 46. Display assembly 1 thus appears black to observer 4.

In FIG. 2B, liquid crystal display cell 8 is deactivated, whereas OLED display cell 30 is activated. Liquid crystal display cell 8 is therefore transparent and lets the light emitted by OLED display cell 30 pass through.

More specifically, ambient light 52, linearly polarized by absorbent polarizer 22, undergoes a 90° rotation when it passes through reflective liquid crystal display cell 8, and is then transmitted without modification by reflective polarizer 26 whose axis of transmission is perpendicular to the axis of transmission of absorbent polarizer 22. Ambient light 52 is then circularly polarized by circular polarizer 46, which transmits the light without absorption given that the axis of transmission of absorbent polarizer 48 is oriented parallel to the axis of transmission of reflective polarizer 26. Finally, ambient light 52 penetrates OLED display cell 30. In OLED display cell 30, ambient light 52 is reflected by transparent lower electrode 42. At the moment of reflection, the rotational direction of circular polarization of the light is reversed so that, when the light passes through circular polarizer 46 again it is absorbed by the latter. Further, half of the light emitted by OLED display cell 30 is absorbed by absorbent polarizer 48, whereas the other half of the light, which is linearly polarized, passes firstly through reflective polarizer 26 without modification, since the axis of transmission of reflective polarizer 26 is oriented parallel to the axis of transmission of absorbent polarizer 48 belonging to circular polarizer 46. On passing through liquid crystal display cell 8, the polarized light undergoes a 90° rotation, so that its direction of polarization is finally parallel to the axis of transmission of absorbent polarizer 22 which it traverses without being absorbed. The displayed information therefore appears light on a dark background.

In FIG. 2C, liquid crystal display cell 8 is activated in reflective mode and OLED display cell 30 is switched off. Liquid crystal display cell 8 thus reflects ambient light 52, so that the information that it displays appears light on a dark background provided by OLED display cell 30. The contrast between the light pixels of liquid crystal display cell 8 and the dark background of OLED display cell 30 makes it possible to display information in a very readable manner.

More specifically, in the zones of liquid crystal display cell 8 which are not switched, ambient light 52, linearly polarized by absorbent polarizer 22, undergoes a 90° rotation when it passes through liquid crystal display cell 8, and is then transmitted without modification by reflective polarizer 26 whose axis of transmission is perpendicular to the axis of transmission of absorbent polarizer 22. Ambient light 52 is then circularly polarized by circular polarizer 46, which transmits the light without absorption given that the axis of transmission of absorbent polarizer 48 is oriented parallel to the axis of transmission of reflective polarizer 26. Finally, ambient light 52 penetrates OLED display cell 30 where it is reflected by transparent lower electrode 42. At that moment, the rotational direction of circular polarization is reversed so that, when the light passes through circular polarizer 46 again it is absorbed by the latter. Further, in the zones of liquid crystal display cell 8 which are switched, after being linearly polarized by absorbent polarizer 22, ambient light 52 passes through liquid crystal display cell 8 without modification, so that the direction of polarization of ambient light 52 is perpendicular to the axis of transmission of reflective polarizer 26 and therefore parallel to the axis of reflection of said polarizer 26. Consequently, ambient light 52 is reflected by reflective polarizer 26 in the direction of liquid crystal display cell 8. In the zones of liquid crystal display cell 8 which are switched, the liquid crystal molecules do not modify the polarization direction of ambient light 52 when the latter passes through liquid crystal display cell 8 again, so that ambient light 52 is not absorbed by absorbent polarizer 22 during its return travel, which makes the reflective mode of display assembly 1 possible.

In FIG. 2D, liquid crystal display cell 8 is activated in reflective mode and OLED display cell 30 is switched on. In this case, the light emitted by OLED display cell 30 is absorbed by absorbent polarizer 22 in the active areas of liquid crystal display cell 8 where information is displayed. More specifically, ambient light 52 is linearly polarized by absorbent polarizer 22 then passes without modification through the areas of liquid crystal display cell 8 which are switched. Since the axis of transmission of absorbent polarizer 22 is perpendicular to the axis of transmission of reflective polarizer 26, ambient light 52 is reflected by reflective polarizer 26 and then passes without modification through the switched areas of liquid crystal display cell 8 again. Finally, ambient light 52 passes through absorbent polarizer 22 without being absorbed and is perceptible to observer 4, which allows liquid crystal display cell 8 to display information in the reflective mode. As regards the remaining ambient light 52, this is linearly polarized by absorbent polarizer 22 and then passes through the non-switched areas of liquid crystal display cell 8. As it passes therethrough, the polarization direction of ambient light 52 is rotated by 90°, so that when the light emerges from liquid crystal display cell 8, its polarization direction is parallel to the axis of transmission of reflective polarizer 26. The light then passes through reflective polarizer 26 without modification and is then circularly polarized by circular polarizer 46. Ambient light 52 then penetrates OLED display cell 30 where it is reflected by transparent lower electrode 42. At that moment, the rotational direction of circular polarization is reversed so that, when the light passes through circular polarizer 46 again it is absorbed by the latter. Further, half of the light emitted by OLED display cell 30 is absorbed by absorbent polarizer 48, whereas the other half of the light emitted by OLED display cell 30 passes through absorbent polarizer 48 and is linearly polarized, then passes through reflective polarizer 26 without modification since the axis of transmission of reflective polarizer 26 is parallel to the axis of transmission of absorbent polarizer 48. In the areas of liquid crystal display cell 8 that are activated, the light passes without modification, so that it is absorbed by absorbent polarizer 22 since its polarization direction is perpendicular to the axis of transmission of absorbent polarizer 22. However, in the areas of liquid crystal display cell 8 that are not activated, the light polarization direction is rotated by 90°, so that this fraction of light passes through absorbent polarizer 22 without being absorbed and is perceptible to observer 4.

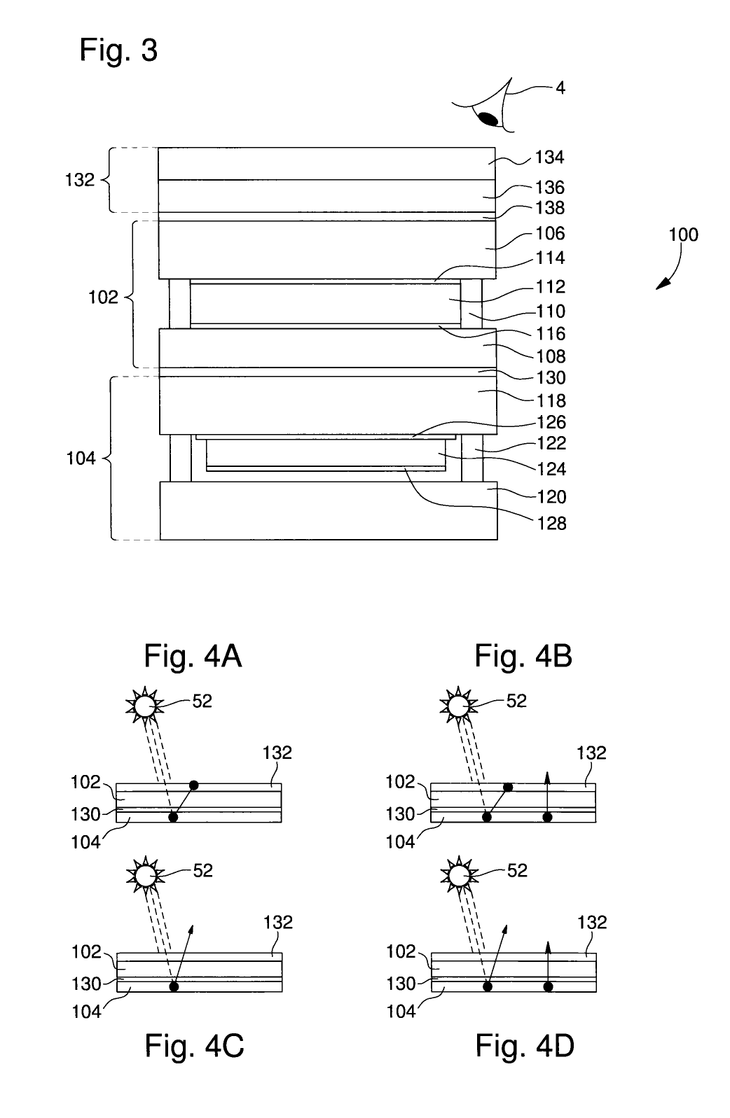

FIG. 3 is a cross-sectional view of a variant embodiment of the display assembly 1 according to the invention illustrated in FIG. 1. Designated as a whole by the general reference numeral 100, the display assembly illustrated in FIG. 3 includes a liquid crystal display cell 102 disposed above an OLED display cell 104. Liquid crystal display cell 102 is a single polarizer cell whose liquid crystals are vertically aligned. Liquid crystal display cell 102 includes a front substrate 106 arranged on the side of the observer 4 and a rear substrate 108 which extends parallel to and remote from front substrate 106. Front substrate 106 and rear substrate 108 are joined to each other by a sealing frame 110 which delimits a closed volume for containing liquid crystals 112 which are vertically aligned. Transparent electrodes 114 are arranged on the lower face of front substrate 106 and transparent counter electrodes 116 are arranged on the upper face of rear substrate 108.

OLED display cell 104 includes a transparent substrate 118 made of glass or of a plastic material and an encapsulation cover 120 which extends parallel to and remote from substrate 118. Substrate 118 and encapsulation cover 120 are joined to each other by a sealing frame 122 which delimits a closed volume shielded from air and humidity to contain a stack of light-emitting layers 124. A transparent upper electrode 126 and a reflective lower electrode 128 are structured on either side of the stack of light-emitting layers 124.

With respect to observer 4, liquid crystal display cell 102 is disposed above OLED display cell 104. Preferably, liquid crystal display cell 102 is bonded on OLED display cell 104 by means of an adhesive layer 130 formed of an adhesive film or of a liquid adhesive layer. The adhesive used to bond liquid crystal display cell 102 on OLED display cell 104 may be transparent or slightly diffusing depending on whether specular or diffuse reflection is required.

Finally, a circular polarizer 132 formed of an absorbent polarizer 134 and a quarter-wave plate 136 is bonded on liquid crystal display cell 102 by means of a transparent adhesive layer 138.

Generally, the ambient light is circularly polarized on passing through the assembly formed by absorbent polarizer 134 and quarter-wave plate 136. At rest, the liquid crystals do not modify the polarization of light. Thus, the circularly polarized light propagates through liquid crystal display cell 102 and OLED display cell 104 and is reflected onto reflective lower electrode 128. At the moment of reflection on reflective lower electrode 128, the direction of rotation of the circular polarization of the light is reversed so that, when the light passes through circular polarizer 132 again it is absorbed by said circular polarizer 132. Display assembly 100 therefore appears black.

When an electric field is applied to selected electrodes of liquid crystal display cell 102, the liquid crystals are reoriented and modify the polarization of light, so that this circular polarization becomes linear at the moment of reflection on reflective lower electrode 128 of OLED display cell 104. The light reflected by reflective lower electrode 128 is thus not absorbed by absorbent polarizer 134 during its return travel and makes the reflective mode of display assembly 100 possible.

FIGS. 4A to 4D illustrate schematically the operating mode of display assembly 100 illustrated in FIG. 3 depending on whether or not liquid crystal display cell 102 or OLED display cell 104 is in use. More specifically, in FIG. 4A, liquid crystal display cell 102 and OLED display cell 104 are both switched off. Liquid crystal display cell 102 is therefore transparent and does not modify the polarization of ambient light 52. Circularly polarized by circular polarizer 132, ambient light 52 passes without modification through liquid crystal display cell 102 and OLED display cell 104 before being reflected on reflective lower electrode 128. At the moment of reflection on reflective lower electrode 128, the direction of rotation of the circular polarization of the light is reversed so that when the light passes through circular polarizer 132 again it is absorbed. Display assembly 100 therefore appears black.

In FIG. 4B, liquid crystal display cell 102 is deactivated, whereas OLED display cell 104 is activated. Circularly polarized by circular polarizer 132, ambient light 52 passes without modification through liquid crystal display cell 102 and OLED display cell 104 before being reflected by reflective lower electrode 128. At that moment, the direction of rotation of the circular polarization of the light is reversed so that when the light passes through circular polarizer 132 again it is absorbed by the latter. Conversely, the light emitted by OLED display cell 104 passes through liquid crystal display cell 102 and circular polarizer 132 so that it is perceptible to the observer 4. The information displayed by OLED display cell 104 is therefore displayed on a dark background.

In FIG. 4C, liquid crystal display cell 102 is activated, whereas OLED display cell 104 is switched off. In the areas of liquid crystal display cell 102 which are not switched, ambient light 52 is circularly polarized by circular polarizer 132 and then passes without modification through liquid crystal display cell 102 and OLED display cell 104 before being reflected by reflective lower electrode 128. At that moment, the rotational direction of circular polarization is reversed so that, when the light passes through circular polarizer 132 again it is absorbed by the latter. In the areas of liquid crystal display cell 102 that are switched, the liquid crystal molecules modify the circular polarization of ambient light 52 so that this circular polarization becomes linear at the moment of reflection of ambient light 52 on reflective lower electrode 128 of OLED display cell 104. The light reflected by reflective lower electrode 128 is thus not absorbed by absorbent polarizer 134 during its return travel which makes the reflective mode of display assembly 100 possible.

In FIG. 4D, liquid crystal display cell 102 and OLED display cell 104 are both activated. In the areas of liquid crystal display cell 102 that are switched, the ambient light 52 reflected by reflective lower electrode 128 is not absorbed by absorbent polarizer 134 and is perceptible to observer 4, which allows liquid crystal display cell 102 to display information in the reflective mode. Further, the light emitted by OLED display cell 104 passes through liquid crystal display cell 102 and circular polarizer 132 so that it is perceptible to observer 4.

It is important to note that other alignment modes of the liquid crystal molecules, such as the twisted nematic or super-twisted nematic modes, may also be envisaged for producing display assembly 100 according to the invention illustrated in FIG. 3.

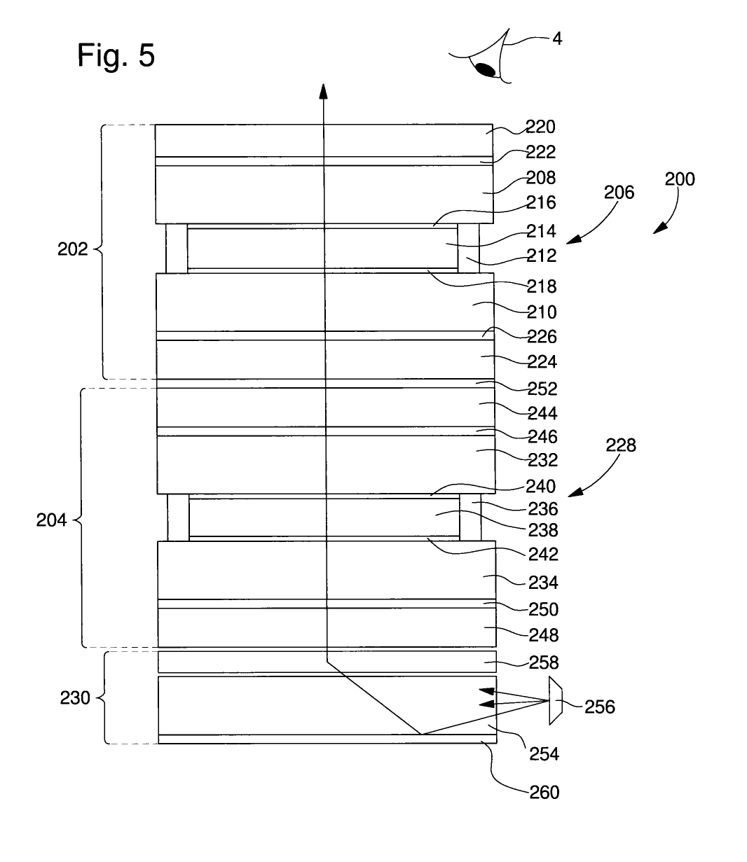

FIG. 5 is a cross-sectional view of a second embodiment of a display assembly according to the invention. Designated as a whole by the general reference numeral 200, this display assembly includes a first reflective display device 202 located on the side of observer 4, and a second emissive display device 204, arranged underneath the first reflective display device 202.

According to the invention, the first reflective display device 202, which is reflective in a first switching state and which is transmissive in a second switching state, includes an upper liquid crystal display cell 206. All liquid crystal phases, such as twisted nematic, super-twisted nematic or vertically aligned, may be envisaged. Likewise, all addressing schemes, such as direct addressing, active matrix addressing, or passive matrix multiplexing addressing may be envisaged.

Upper liquid crystal display cell 206 includes a front substrate 208 located on the side of the observer 4 and a rear substrate 210 which extends parallel to and remote from front substrate 208. These two front and rear substrates 208, 210 are made of a transparent material such as glass or plastic. They are joined to each other by a sealing frame 212 which delimits a closed volume for containing a liquid crystal 214 whose optical properties are modified by application of a suitable voltage at a particular crosspoint between electrodes 216 arranged on a lower face of front substrate 208 and counter electrodes 218 arranged on an upper face of rear substrate 210. Electrodes 216 and counter electrodes 218 are made of a transparent electrically conductive material such as indium tin oxide or indium zinc oxide.

An absorbent polarizer 220 is bonded on an upper face of front substrate 208 by means of a transparent adhesive layer 222. This transparent adhesive layer 222 may be formed of an adhesive film or of a liquid adhesive layer. Absorbent polarizer 220 may be, for example, an iodine or dye type polarizer. A reflective polarizer 224 is bonded on a lower face of rear substrate 210 by means of an adhesive layer 226. This adhesive layer 226 may be transparent or slightly diffusive depending on whether specular or diffuse reflection is required. Reflective polarizer 224 may be of the wire grid polarizer type. It may also be a dual brightness enhancement film (DBEF) or APF type polarizer. These polarizers are both sold by the American company 3M®.

Also according to the invention, the second emissive display device 204 includes a lower transmissive liquid crystal display cell 228 associated with a backlight device 230. Lower liquid crystal display cell 228 can be switched between a transmissive mode and an absorbent mode. All liquid crystal phases, such as twisted nematic, super-twisted nematic or vertically aligned, may be envisaged. Likewise, any type of addressing, such as direct addressing, active or passive matrix addressing may be envisaged. The lower liquid crystal display cell 228 is optimised to allow maximum light to pass through from backlight device 230 in transmissive mode, and to block light as much as possible in the absorbent state, thus providing excellent contrast.

More specifically, lower liquid crystal display cell 228 includes a front substrate 232 arranged on the side of the observer 4 and a rear substrate 234 which extends parallel to and remote from front substrate 232. These front and rear substrates 232, 234 are made of a transparent material such as glass or plastic. They are joined to each other by a sealing frame 236 which delimits a closed volume for containing a liquid crystal 238. Electrodes 240 are arranged on a lower face of front substrate 232 and counter electrodes 242 are arranged on an upper face of rear substrate 234. These electrodes 240 and counter electrodes 242 are made of a transparent electrically conductive material such as tin indium oxide (ITO).

An absorbent polarizer 244 is bonded on an upper face of front substrate 232 by means of a transparent adhesive layer 246. This transparent adhesive layer 246 may be formed of an adhesive film or of a liquid adhesive layer. An absorbent polarizer 248 is bonded on a lower face of rear substrate 234 by means of a transparent adhesive layer 250.

According to the invention, the upper liquid crystal display cell 206 is disposed above lower liquid crystal display cell 228. Preferably, upper liquid crystal display cell 206 is bonded on lower liquid crystal display cell 228 via a transparent adhesive layer 252. Consequently, the problems of stray reflections between the two display cells which would degrade the optical quality of display assembly 200 are avoided.

Finally, backlight device 230 is placed underneath lower liquid crystal display cell 228. This backlight device 230 includes a light guide 254 in which is injected the light emitted by one or more light sources 256. Light guide 254 is placed between a reflective film 260 placed underneath light guide 254 and a film or a combination of light enhancement films 258, for example a diffuser film and/or prismatic films of the BEF (brightness enhancement film) type or a reflective polarizer of the DBEF (dual brightness enhancement film) or APF type. As a result of reflective film 260 and extraction structures arranged in the upper surface of light guide 254, the light emitted by light source 256 and injected in light guide 254 is extracted upwards therefrom and passes in succession through lower liquid crystal display cell 228 and upper liquid crystal display cell 206.

According to a feature of the invention, the axis of transmission of reflective polarizer 224 of upper liquid crystal display cell 206 is parallel to the axis of transmission of absorbent polarizer 244 of lower liquid crystal display cell 228. According to a variant, absorbent polarizer 244 of lower liquid crystal display cell 228 can be omitted, which makes it possible to achieve a saving in terms of space and manufacturing costs. However, the use of this absorbent polarizer 244 has the advantage of ensuring improved display contrast in the emissive mode.

It goes without saying that this invention is not limited to the embodiments that have just been described and that various simple alterations and variants can be envisaged by those skilled in the art without departing from the scope of the invention as defined by the annexed claims.

### LIST OF PARTS

Display assembly 1
First reflective display device 2
Observer 4
Second emissive display device 6
Liquid crystal display cell 8
Front substrate 10
Rear substrate 12
Sealing frame 14
Liquid crystal 16
Transparent electrodes 18
Transparent counter electrodes 20
Absorbent polarizer 22
Adhesive layer 24
Reflective polarizer 26
Adhesive layer 28
Emissive display cell 30
Substrate 32
Encapsulation cover 34
Sealing frame 36
Light-emitting layers 38
Transparent upper electrode 40
Reflective lower electrode 42
Transparent adhesive layer 44
Circular polarizer 46
Absorbent polarizer 48
Quarter wave plate 50
Adhesive layer 51
Ambient light 52
Display assembly 100
Liquid crystal display cell 102
OLED display cell 104
Front substrate 106
Rear substrate 108
Sealing frame 110
Liquid crystals 112
Transparent electrodes 114
Transparent counter electrodes 116
Substrate 118
Encapsulation cover 120
Sealing frame 122
Light-emitting layers 124
Upper transparent electrode 126
Lower reflective electrode 128
Adhesive layer 130
Circular polarizer 132
Absorbent polarizer 134
Quarter wave plate 136
Adhesive layer 138
Display assembly 200
First reflective display device 202
Second emissive display device 204
Upper liquid crystal display cell 206
Front substrate 208
Rear substrate 210
Sealing frame 212
Liquid crystal 214
Electrode 216
Counter electrode 218
Absorbent polarizer 220
Transparent adhesive layer 222
Reflective polarizer 224
Adhesive layer 226
Lower liquid crystal display cell 228
Backlight device 230
Front substrate 232
Rear substrate 234
Sealing frame 236
Liquid crystal 238
Electrode 240
Counter electrode 242
Absorbent polarizer 244
Transparent adhesive layer 246
Absorbent polarizer 248
Transparent adhesive layer 250
Transparent adhesive layer 252
Light guide 254
Light source 256
Light enhancement film 258
Reflective film 260

What is claimed is:

1. A display assembly for a portable object, wherein the display assembly includes a first reflective display device located on the side of an observer, wherein the first reflective display device is capable of switching between a transparent state when at rest and a reflective state when activated, wherein a second emissive display device is disposed underneath the first reflective display device.

2. The display assembly according to claim 1, wherein the first reflective display device is bonded on the second emissive display device by means of an adhesive layer.

3. The display assembly according to claim 2, wherein the adhesive layer is formed of an adhesive film or a liquid adhesive layer.

4. The display assembly according to claim 1, wherein the first reflective display device includes a liquid crystal display cell arranged to switch between a reflective state and a transparent state and wherein the second emissive display device includes an emissive organic light-emitting diode display cell arranged to switch between an active state wherein the display cell emits light and a rest state wherein the display cell does not emit light.

5. The display assembly according to claim 2, wherein the first reflective display device includes a liquid crystal display cell arranged to switch between a reflective state and a transparent state and wherein the second emissive display device includes an emissive organic light-emitting diode display cell arranged to switch between an active state wherein the display cell emits light and a rest state wherein the display cell does not emit light.

6. The display assembly according to claim 3, wherein the first reflective display device includes a liquid crystal display cell arranged to switch between a reflective state and a transparent state and wherein the second emissive display device includes an emissive organic light-emitting diode display cell arranged to switch between an active state wherein the display cell emits light and a rest state wherein the display cell does not emit light.

7. The display assembly according to claim 4, wherein the reflective liquid crystal display cell is disposed between an absorbent upper polarizer and a reflective lower polarizer and wherein a circular polarizer comprising an absorbent polarizer and a quarter-wave plate is disposed between the reflective lower polarizer and the emissive display cell.

8. The display assembly according to claim 5, wherein the reflective liquid crystal display cell is disposed between an absorbent upper polarizer and a reflective lower polarizer and wherein a circular polarizer comprising an absorbent polarizer and a quarter-wave plate is disposed between the reflective lower polarizer and the emissive display cell.

9. The display assembly according to claim 6, wherein the reflective liquid crystal display cell is disposed between an absorbent upper polarizer and a reflective lower polarizer and wherein a circular polarizer comprising an absorbent polarizer and a quarter-wave plate is disposed between the reflective lower polarizer and the emissive display cell.

10. The display assembly according to claim 7, wherein the reflective lower polarizer and the absorbent polarizer each have an axis of transmission, and wherein these axes of transmission are parallel to each other.

11. The display assembly according to claim 8, wherein the reflective lower polarizer and the absorbent polarizer each have an axis of transmission, and wherein these axes of transmission are parallel to each other.

12. The display assembly according to claim 9, wherein the reflective lower polarizer and the absorbent polarizer each have an axis of transmission, and wherein these axes of transmission are parallel to each other.

13. The display assembly according to claim 4, wherein a circular polarizer includes an absorbent polarizer and a quarter-wave plate, wherein the circular polarizer is disposed on a front face of the reflective liquid crystal display cell, and wherein the emissive organic light-emitting diode display cell includes a reflective lower electrode.

14. The display assembly according to claim 5, wherein a circular polarizer includes an absorbent polarizer and a quarter-wave plate, wherein the circular polarizer is disposed on a front face of the reflective liquid crystal display cell, and wherein the emissive organic light-emitting diode display cell includes a reflective lower electrode.

15. The display assembly according to claim 6, wherein a circular polarizer includes an absorbent polarizer and a quarter-wave plate, wherein the circular polarizer is disposed on a front face of the reflective liquid crystal display cell, and wherein the emissive organic light-emitting diode display cell includes a reflective lower electrode.

16. The display assembly according to claim 1, wherein the first reflective display device includes an upper liquid crystal display cell arranged to switch between a reflective state and a transparent state, and wherein the second emissive display device includes a lower liquid crystal display cell arranged to switch between a state wherein the display cell is absorbent and a state wherein the display cell allows the light emitted by a backlight device disposed underneath the liquid crystal display cell to pass through.

17. The display assembly according to claim 2, wherein the first reflective display device includes an upper liquid crystal display cell arranged to switch between a reflective state and a transparent state, and wherein the second emissive display device includes a lower liquid crystal display cell arranged to switch between a state wherein the display cell is absorbent and a state wherein the display cell allows the light emitted by a backlight device disposed underneath the liquid crystal display cell to pass through.

18. The display assembly according to claim 3, wherein the first reflective display device includes an upper liquid crystal display cell arranged to switch between a reflective state and a transparent state, and wherein the second emissive display device includes a lower liquid crystal display cell arranged to switch between a state wherein the display cell is absorbent and a state wherein the display cell allows the light emitted by a backlight device disposed underneath the liquid crystal display cell to pass through.

19. The display assembly according to claim 16, wherein an absorbent polarizer is disposed on an upper face of the upper liquid crystal display cell, wherein a reflective polarizer is disposed on a lower face of the upper liquid crystal display cell, and wherein an absorbent polarizer is bonded on a lower face of the lower liquid crystal display cell.

20. The display assembly according to claim 17, wherein an absorbent polarizer is disposed on an upper face of the upper liquid crystal display cell, wherein a reflective polarizer is disposed on a lower face of the upper liquid crystal display cell, and wherein an absorbent polarizer is bonded on a lower face of the lower liquid crystal display cell.

21. The display assembly according to claim 18, wherein an absorbent polarizer is disposed on an upper face of the upper liquid crystal display cell, wherein a reflective polarizer is disposed on a lower face of the upper liquid crystal display cell, and wherein an absorbent polarizer is bonded on a lower face of the lower liquid crystal display cell.

22. The display assembly according to claim 19, wherein an absorbent polarizer is arranged on an upper face of the lower liquid crystal display cell.

23. The display assembly according to claim 20, wherein an absorbent polarizer is arranged on an upper face of the lower liquid crystal display cell.

24. The display assembly according to claim 21, wherein an absorbent polarizer is arranged on an upper face of the lower liquid crystal display cell.

25. The display assembly according to claim 19, wherein the reflective polarizer and the absorbent polarizer each have an axis of transmission and wherein these axes of transmission are parallel to each other.

26. The display assembly according to claim 22, wherein the reflective polarizer and the absorbent polarizer each have an axis of transmission and wherein these axes of transmission are parallel to each other.
